(19) United States
(12) Patent Application Publication
(10) Pub. No.: US 2025/0201541 A1
(43) Pub. Date: Jun. 19, 2025

(54) ARCING DETECTION SENSOR AND PLASMA TREATING APPARATUS INCLUDING THE SAME

(71) Applicant: SAMSUNG ELECTRONICS CO., LTD., SUWON-SI (KR)

(72) Inventors: Dohoon Kwon, Suwon-si (KR); Sangki Nam, Suwon-si (KR); Taewoo Kim, Suwon-si (KR); Sejin Oh, Suwon-si (KR); Kyunggon You, Suwon-si (KR); Changsoon Lim, Suwon-si (KR); Jonghun Pi, Suwon-si (KR)

(21) Appl. No.: 18/953,352

(22) Filed: Nov. 20, 2024

(30) Foreign Application Priority Data
Dec. 14, 2023 (KR) 10-2023-0182240

(51) Int. Cl. H01J 37/32

(52) U.S. Cl. CPC H01J 37/32944; H01J 37/32522; H01J 37/32577

(57) ABSTRACT

An arcing detection sensor comprises a substrate portion having a plurality of through holes; a plurality of circular conductive patterns, each circular conductive pattern arranged along a circumference of a respective through hole of the plurality of through holes; and a coil conductive pattern surrounding the plurality of circular conductive patterns. Each circular conductive pattern is configured to detect a voltage of a respective conductive wire passing through the respective through hole, and the coil conductive pattern is configured to detect currents of the conductive wires passing through the plurality of through holes.

### CROSS-REFERENCE TO RELATED APPLICATION

This application claims priority under 35 U.S.C. § 119 to Korean Patent Application No. 10-2023-0182240, filed on Dec. 14, 2023, in the Korean Intellectual Property Office, the disclosure of which is incorporated by reference herein in its entirety.

### TECHNICAL FIELD

Embodiments of the present disclosure relate to an arcing detection sensor and a plasma treating apparatus including the same.

### DISCUSSION OF RELATED ART

A process for manufacturing semiconductor devices includes a plasma process, such as plasma-induced deposition, plasma etching, and plasma cleaning. The plasma process can be performed in plasma chambers using high-frequency power. Using high-frequency power can lead to arcing within the plasma chamber, and arcing can cause damage to the semiconductor devices and the plasma chamber, leading to performance issues, reliability problems, and increased maintenance requirements. Research is conducted to develop effective solutions for mitigating these effects and producing high-quality semiconductor devices.

### SUMMARY

Embodiments of the present disclosure provide an arcing detection sensor with increased arcing detection ability and a plasma treating apparatus including the same.

According to embodiments of the present disclosure, an arcing detection sensor comprises a substrate portion having a plurality of through holes; a plurality of circular conductive patterns, each circular conductive pattern arranged along a circumference of a respective through hole of the plurality of through holes; and a coil conductive pattern surrounding the plurality of circular conductive patterns; wherein each circular conductive pattern is configured to detect a voltage of a respective conductive wire passing through the respective through hole, and the coil conductive pattern is configured to detect currents of the conductive wires passing through the plurality of through holes.

According to embodiments of the present disclosure, a plasma treating apparatus comprises a plasma chamber configured to provide a treatment space; a lower electrode structure configured to support a wafer and including a heater configured to heat the wafer; an upper electrode structure disposed above the lower electrode structure and facing the lower electrode structure; a power source configured to apply power to the heater; and an arcing detection sensor positioned between the heater and the power source. The arcing detection sensor comprises a substrate portion having a plurality of through holes; a plurality of circular conductive patterns, each circular conductive pattern arranged along a circumference of a respective through hole of the plurality of through holes; and a coil conductive pattern surrounding the plurality of circular conductive patterns, wherein each circular conductive pattern is configured to detect a voltage of a respective conductive wire passing through the respective through hole, and the coil conductive pattern is configured to detect currents of the conductive wires passing through the plurality of through holes.

According to embodiments of the present disclosure, an arcing detection sensor comprises a substrate portion having a first through hole, a second through hole, a third through hole, and a fourth through hole horizontally spaced apart; a plurality of circular conductive patterns, wherein the plurality of circular conductive patterns comprise a first circular conductive pattern arranged along a circumference of the first through hole, a second circular conductive pattern arranged along a circumference of the second through hole, a third circular conductive pattern arranged along a circumference of the third through hole, and a fourth circular conductive pattern arranged along a circumference of the fourth through hole; and a coil conductive pattern surrounding the plurality of circular conductive patterns, wherein each circular conductive pattern is configured to detect a voltage of a respective conductive wire passing through the respective through hole by electric field coupling, and the coil conductive pattern is configured to detect currents of the conductive wires passing through the plurality of through holes by magnetic field coupling.

### BRIEF DESCRIPTION OF THE DRAWINGS

Embodiments will be more clearly understood from the following detailed description taken in conjunction with the accompanying drawings in which:

FIG. 1 is a schematic configuration diagram of a plasma treating apparatus according to some embodiments;

FIG. 2 is a detailed view of portion EX of FIG. 1;

FIG. 3 is a cross-sectional view of an arcing detection sensor at a first vertical level LV1 in FIG. 2;

FIG. 4 is a cross-sectional view of an arcing detection sensor along a line corresponding to the first vertical level LV1 in FIG. 2;

FIGS. 5A and 5B are graphs showing a degree of detection of an arcing signal by a conventional arcing detection sensor;

FIGS. 6A and 6B are graphs showing a degree of detection of an arcing signal by an arcing detection sensor according to some embodiments; and

FIG. 7 is a flowchart of a method of detecting arcing by an arcing detection sensor according to some embodiments.

### DETAILED DESCRIPTION OF THE EMBODIMENTS

Hereinafter, embodiments are described in detail with reference to the accompanying drawings. The same reference numerals are used for the same components in the drawings, and duplicate descriptions thereof are omitted.

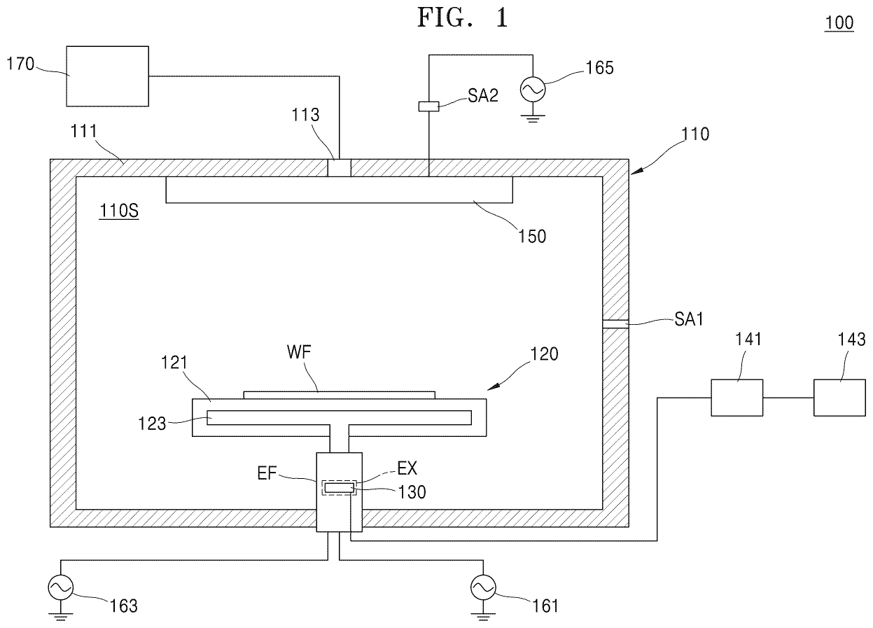

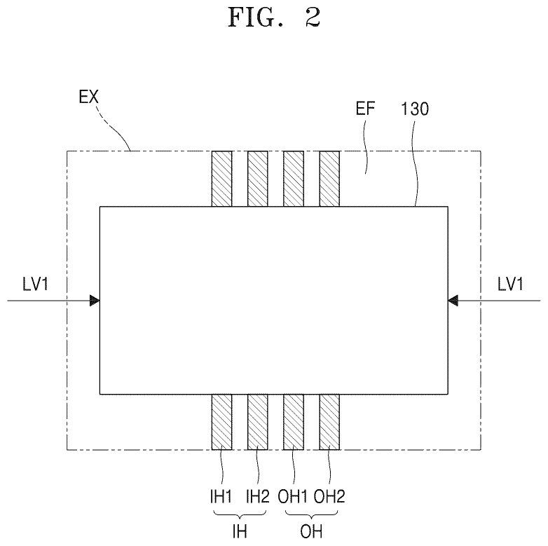

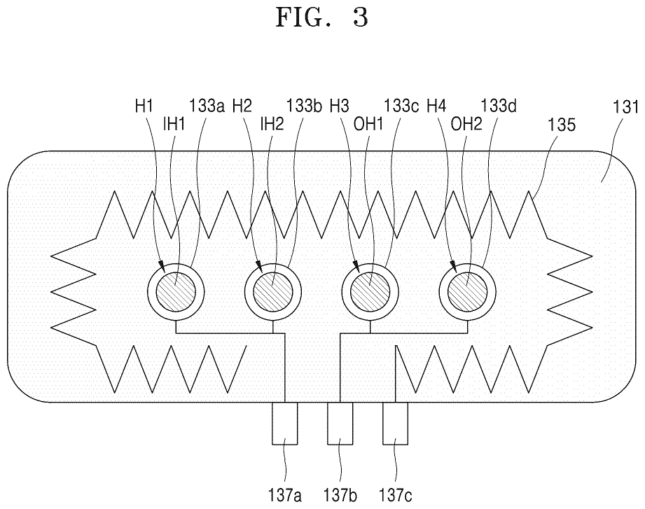

FIG. 1 illustrates a schematic configuration diagram of a plasma treating apparatus 100 according to some embodiments. FIG. 2 provides a detailed view of portion EX from FIG. 1. FIG. 3 depicts a cross-sectional view of an arcing detection sensor 130 at a first vertical level LV1, as shown in FIG. 2.

Referring to FIGS. 1, 2, and 3, the plasma treating apparatus 100 may be configured to perform a plasma treatment on a wafer WF. The plasma treatment may include, for example, an etching process, a deposition process, a cleaning process, and the like. In some embodiments, the plasma treating apparatus 100 may be a capacitive coupled plasma (CCP) system, but is not limited thereto. The plasma treating apparatus 100 may also include an inductively coupled plasma (ICP) system, an electron cyclotron resonance (ECR) plasma system, or a helical plasma system.

The plasma treating apparatus 100 may include a plasma chamber 110, a lower electrode structure 120, and an upper electrode structure 150.

The plasma chamber 110 may include a chamber body 111 and a gas supply port 113. The chamber body 111 may provide a treatment space 110S in which the plasma treatment on the wafer WF may be performed. In some examples, the chamber body 111 may be a vacuum chamber having a cylindrical shape. An upper portion of the chamber body 111 may include a disc-shaped dielectric window. The chamber body 111 may be made of a material such as aluminum or stainless steel.

The gas supply port 113 may be disposed on the ceiling of the chamber body 111, penetrating the ceiling in a vertical direction. The gas supply port 113 may be connected to a gas supply device 170. A process gas provided from the gas supply device 170 into the treatment space 110S of the chamber body 111 through the gas supply port 113. In some cases, the process gas may var based on the specific plasma treatment process, y. For example, in a plasma etching process, the process gas may be a plasma gas, while in a deposition process, the process gas may be a deposition gas. The gas supply port 113 may be configured to deliver the process gas to the upper electrode structure 150, which then supplies the process gas to the treatment space 110S in the form of a shower. This configuration allows for the uniform distribution of the process gas throughout the treatment space 110S, ensuring consistent plasma treatment across the entire wafer WF surface.

A first sensor SA1 may be positioned in a sidewall of the chamber body 111. For example, the first sensor SA1 may be an optical sensor configured to detect the intensity of light generated from plasma in the treatment space 110S. The first sensor SA1 may output a signal for detecting arcing based on the detected intensity of light. In some cases, the first sensor SA1 may include a viewport configured to collect light generated from the plasma and a lens configured to condense and amplify the intensity of the light collected by the viewport. The first sensor SA1 may collect light generated from the plasma through the viewport. The first sensor SA1 may detect the intensity of the light by making the collected light incident on the lens. The first sensor SA1 may be configured to electrically transmit and receive a signal to and from an arcing detector 141. In this case, the arcing detector 141 may receive an arcing signal from the first sensor SA1. The arcing detector 141 may store arcing information included in the arcing signal. Additionally, the arcing detector 141 may detect whether arcing has occurred within the plasma chamber 110 based on the arcing information included in the arcing signal received from the first sensor SA1.

An exhaust port (not shown) may be disposed on the bottom of the chamber body 111. The exhaust port may be connected to an exhaust device (not shown). Air in the treatment space 110S of the chamber body 111 may flow out to the exhaust device through the exhaust port.

The lower electrode structure 120 may be positioned within the treatment space 110S of the plasma chamber 110. The lower electrode structure 120 may include a lower electrode 121 and a heater 123.

The lower electrode 121 may be configured to support the wafer WF within the treatment space 110S. For example, the lower electrode 121 may be an electrostatic chuck (ESC) configured to support and fix the wafer WF using static electricity. The lower electrode 121 may include, for example, a ceramic material such as aluminum nitride (AlN), or a metal material such as aluminum or a nickel-based alloy. In some examples, the lower electrode 121 may have a disk shape. A plurality of support pins (not shown) may be disposed on an upper surface of the lower electrode 121. The plurality of support pins may protrude from the upper surface of the lower electrode 121. The plurality of support pins may separate the wafer WF from the lower electrode 121.

The lower electrode 121 may be connected to a first power source 161, which applies bias power to the lower electrode 121. The applied bias power induces plasma ions formed in the treatment space 110S during plasma treatment to be incident on the wafer WF. The incident plasma ions on the wafer WF enable the performance of a plasma etching process or a plasma deposition process on the wafer WF.

The heater 123 may be positioned inside the lower electrode 121. The heater 123 may be configured to control the temperature of the wafer WF supported by the lower electrode 121. In some examples, the heater 123 may have a disk shape. An inner conductive wire IH and an outer conductive wire OH may be positioned inside the heater 123. The inner conductive wire IH may pass through a first through hole H1 of the arcing detection sensor 130 to enter the inside of the heater 123. After being wound inside the heater 123, the inner conductive wire IH may exit from the inside of the heater 123 and pass through a second through hole H2. The outer conductive wire OH may pass through a third through hole H3 of the arcing detection sensor 130 to enter the inside of the heater 123. After being wound inside the heater 123, the outer conductive wire OH may exit from the inside of the heater 123 and pass through a fourth through hole H4. The inner conductive wire IH may be wound in a center area of the heater 123 having a disk shape. The outer conductive wire OH may be wound in an edge area of the heater 123. The inner conductive wire IH passing through the first through hole H1 may be referred to as a first inner conductive wire IH1. The inner conductive wire IH passing through the second through hole H2 may be referred to as a second inner conductive wire IH2. The outer conductive wire OH passing through the third through hole H3 may be referred to as a first outer conductive wire OH1. The outer conductive wire OH passing through the fourth through hole H4 may be referred to as a second outer conductive wire OH2.

The heater 123 may be connected to a second power source 163. The second power source 163 may apply alternating current power to the inner conductive wire IH and the outer conductive wire OH wound inside the heater 123. The alternating current power may be applied to the inner conductive wire IH and the outer conductive wire OH of the heater 123 to generate heat. The heat generated by applying the alternating current power to the inner conductive wire IH and the outer conductive wire OH may be transferred to the wafer WF. The heat transferred to the wafer WF may adjust the temperature of the wafer WF.

A power filter EF may be positioned between the heater 123 and the second power source 163. The power filter EF may attenuate the magnitude of electromagnetic noise generated from the heater 123.

The arcing detection sensor 130 may be positioned inside the power filter EF. The arcing detection sensor 130 may include a substrate portion 131 having a plurality of through holes H1, H2, H3, and H4. The arcing detection sensor 130 may also include a plurality of circular conductive patterns 133a, 133b, 133c, and 133d and a coil conductive pattern 135. Each of the plurality of circular conductive patterns 133a, 133b, 133c, and 133d and the coil conductive pattern 135 may be formed on the substrate portion 131.

In some examples, the substrate portion 131 may include a printed circuit board (PCB). The plurality of through holes H1, H2, H3, and H4 may be positioned in a center area of the substrate portion 131. The plurality of through holes H1, H2, H3, and H4 may be horizontally spaced apart from each other in the center area of the substrate portion 131. In some cases, the plurality of through holes H1, H2, H3, and H4 may have a circular shape. The first inner conductive wire IH1, the second inner conductive wire IH2, the first outer conductive wire OH1, and the second outer conductive wire OH2 may penetrate the arcing detection sensor 130 through the plurality of through holes H1, H2, H3, and H4, respectively. For example, the first inner conductive wire IH1 may pass through the first through hole H1. The second inner conductive wire IH2 may pass through the second through hole H2. The first outer conductive wire OH1 may pass through the third through hole H3. The second outer conductive wire OH2 may pass through the fourth through hole H4. In some embodiments, diameters of the plurality of through holes H1, H2, H3, and H4 may be greater than diameters of the first inner conductive wire IH1, the second inner conductive wire IH2, the first outer conductive wire OH1, and the second outer conductive wire OH2, respectively. For example, the through holes H1, H2, H3, and H4 have diameters that are approximately 1.1 to 1.5 times larger than the diameters of the corresponding conductive wires that pass through them. For example, the diameter of the through hole H1 is about 1.1 to 1.5 times the diameter of the first inner conductive wire IH1 that passes through the through hole H1. The diameter of the through hole H2 is about 1.1 to 1.5 times the diameter of the second inner conductive wire IH2 that passes through the through hole H2. The diameter of the through hole H3 is about 1.1 to 1.5 times the diameter of the first outer conductive wire OH1 that passes through the through hole H3. The diameter of the through hole H4 is about 1.1 to 1.5 times the diameter of the second outer conductive wire OH2 that passes through the through hole H4.

In FIG. 3, the substrate portion 131 is illustrated as having four through holes, but is not limited thereto. For example, when the number of conductive wires wound inside the heater 123 is three, the substrate portion 131 may have six through holes.

The plurality of circular conductive patterns 133a, 133b, 133c, and 133d may be formed along circumferences of the plurality of through holes H1, H2, H3, and H4, respectively, on the substrate portion 131. For example, the first circular conductive pattern 133a may surround the first through hole H1. The second circular conductive pattern 133b may surround the second through hole H2. The third circular conductive pattern 133c may surround the third through hole H3. The fourth circular conductive pattern 133d may surround the fourth through hole H4.

The plurality of circular conductive patterns 133a, 133b, 133c, and 133d may each be connected to one of a plurality of connection terminals 137a and 137b disposed on one side of the substrate portion 131. For example, the first circular conductive pattern 133a and the second circular conductive pattern 133b may be connected to the first connection terminal 137a. The third circular conductive pattern 133c and the fourth circular conductive pattern 133d may be connected to the second connection terminal 137b. Since the first circular conductive pattern 133a and the second circular conductive pattern 133b are connected to the first connection terminal 137a, the voltage of the first inner conductive wire IH1 determined using the first circular conductive pattern 133a and the voltage of the second inner conductive wire IH2 determined using the second circular conductive pattern 133b may be determined together as one arcing signal by the arcing detector 141. According to some embodiments, the third circular conductive pattern 133c and the fourth circular conductive pattern 133d are connected to the second connection terminal 137b. In these embodiments, the voltage of the first outer conductive wire OH1 determined using the third circular conductive pattern 133c and the voltage of the second outer conductive wire OH2 determined using the fourth circular conductive pattern 133d may be determined together as one arcing signal by the arcing detector 141.

The voltages flowing through the first inner conductive wire IH1, the second inner conductive wire IH2, the first outer conductive wire OH1, and the second outer conductive wire OH2 passing through the plurality of through holes H1, H2, H3, and H4 may be determined using the plurality of circular conductive patterns 133a, 133b, 133c, and 133d, respectively. For example, the voltage flowing through the first inner conductive wire IH1 passing through the first through hole H1 may be determined using the first circular conductive pattern 133a. The voltage flowing through the second inner conductive wire IH2 passing through the second through hole H2 may be determined using the second circular conductive pattern 133b. The voltage flowing through the first outer conductive wire OH1 passing through the third through hole H3 may be determined using the third circular conductive pattern 133c. The voltage flowing through the second outer conductive wire OH2 passing through the fourth through hole H4 may be determined using the fourth circular conductive pattern 133d. Specifically, the voltage flowing through the first inner conductive wire IH1 may be determined using electric field coupling between the current flowing through the first inner conductive wire IH1 and the first circular conductive pattern 133a surrounding the first through hole H1. The voltage flowing through each of the second inner conductive wire IH2, the first outer conductive wire OH1, and the second outer conductive wire OH2 may be determined in a similar manner to the voltage flowing through the first inner conductive wire IH1.

The coil conductive pattern 135 may surround each of the plurality of through holes H1, H2, H3, and H4 and each of the plurality of circular conductive patterns 133a, 133b, 133c, and 133d. In some examples, the coil conductive pattern 135 may be a conductive pattern formed to have a coil shape. The coil conductive pattern 135 may be configured to measure a current flowing through each of the first inner conductive wire IH1, the second inner conductive wire IH2, the first outer conductive wire OH1, and the second outer conductive wire OH2. The coil conductive pattern 135 may measure the current using, for example, a Rogowski coil method, but is not limited thereto. The Rogowski coil refers to a type of electrical device used for measuring alternating current or high-speed current pulses. The Rogowski coil may include a helical coil of wire with the lead from one end returning through the center of the coil to the other end, so that both terminals are at the same end of the coil.

The coil conductive pattern 135 may be connected to a third connection terminal 137c. Accordingly, the current flowing through each of the first inner conductive wire IH1, the second inner conductive wire IH2, the first outer conductive wire OH1, and the second outer conductive wire OH2 determined using the coil conductive pattern 135 may be determined together as one arcing signal by the arcing detector 141.

The current flowing through each of the first inner conductive wire IH1, the second inner conductive wire IH2, the first outer conductive wire OH1, and the second outer conductive wire OH2 passing through the plurality of through holes H1, H2, H3, and H4, respectively, may be determined using the coil conductive pattern 135. In some examples, the current flowing through each of the first inner conductive wire IH1, the second inner conductive wire IH2, the first outer conductive wire OH1, and the second outer conductive wire OH2 may be determined based on magnetic field coupling between the coil conductive pattern 135 and the current flowing through each of the first inner conductive wire IH1, the second inner conductive wire IH2, the first outer conductive wire OH1, and the second outer conductive wire OH2, and generates a magnetic field around the respective wire. This magnetic field induces a voltage in the coil conductive pattern 135 through the principle of electromagnetic induction. The induced voltage in the coil conductive pattern 135 is proportional to the rate of change of the current flowing through each of the conductive wires IH1, IH2, OH1, and OH2. In some examples, to obtain the current values from the induced voltage, the induced voltage is passed through an integrator circuit (not shown) connected to the coil conductive pattern 135. In some examples, the integrator circuit performs mathematical integration on the induced voltage signal, converting the induced voltage signal from a time differential value to a value proportional to the original current flowing through each of the conductive wires IH1, IH2, OH1, and OH2. The integrator circuit may be implemented using various techniques. In some examples, this process involves a lossy integrator, which is an integrator circuit that accounts for losses in the system. However, the specific implementation of the integrator circuit is not limited to a lossy integrator. According to some embodiments, by measuring the current flowing through each of the conductive wires IH1, IH2, OH1, and OH2 using the coil conductive pattern 135 and the integrator circuit, the arcing detection sensor 130 can detect and monitor arcing events associated with each individual wire. This capability enhances the precision and effectiveness of the arcing detection system in identifying and mitigating arcing occurrences within plasma treating apparatus 100.

The arcing detector 141 may be configured to exchange electrical signals with the arcing detection sensor 130. The arcing detector 141 may receive an arcing signal from the arcing detection sensor 130. The arcing detector 141 may store arcing information included in the arcing signal. For example, the arcing signal may include the current and the voltage of each of the plurality of conductive wires IH1, IH2, OH1, and OH2 determined based on the arcing detection sensor 130. The arcing information may include, for example, the magnitude or shape of the arcing signal. The arcing detector 141 may detect whether arcing has occurred in the plasma chamber 110 based on the arcing information. For example, the arcing detector 141 may determine that arcing has occurred in the plasma chamber 110 when the magnitude of the arcing signal received from the arcing detection sensor 130 changes drastically.

A control device 143 may be configured to exchange electrical signals with the arcing detector 141. The control device 143 may be configured to receive information from the arcing detector 141 regarding whether arcing has occurred. The control device 143 may control the process environment within the plasma chamber 110 to remove arcing that has occurred within the plasma chamber 110. The control device 143 may be implemented as hardware, firmware, software, or a combination thereof. The control device 143 may be a computing device, such as a workstation computer, desktop computer, laptop computer, tablet computer, or similar devices. For example, the control device 143 may include a memory device, such as read only memory (ROM), random access memory (RAM), and a processor configured to perform predetermined operations and algorithms. The processor may be a microprocessor, central processing unit (CPU), graphics processing unit (GPU), or other processing units. Additionally, the control device 143 may include a receiver and a transmitter for receiving and transmitting electrical signals.

The upper electrode structure 150 may be positioned above the lower electrode structure 120 within the treatment space 110S of the plasma chamber 110. The upper electrode structure 150 may be arranged to face the lower electrode structure 120 in a direction perpendicular to the upper surface of the wafer WF. The upper electrode structure 150 may be fixed to the ceiling of the chamber body 111. The upper electrode structure 150 may include, for example, a metal material. The upper electrode structure 150 may supply the process gas supplied from the gas supply device 170 to the treatment space 110S of the plasma chamber 110 in the form of a shower. The upper electrode structure 150 may provide a space for uniformly spreading the process gas introduced through piping into the plasma chamber 110. Accordingly, the upper electrode structure 150 may enable uniform supply of the process gas to the treatment space 110S.

The upper electrode structure 150 may be connected to a third power source 165. The third power source 165 may apply source power to the upper electrode structure 150. The source power may be, for example, radio frequency (RF) power. The source power may generate plasma gas from the process gas supplied from the gas supply device 170.

In some embodiments, the source power is applied to the upper electrode structure 150 and the bias power is applied to the lower electrode structure 120. However, other configurations are also possible. For example, the plasma treating apparatus 100 may be provided with a plurality of source powers having different frequencies. Some of the plurality of source powers may be applied to the upper electrode structure 150, and the others may be applied to the lower electrode structure 120. In another example, a ground potential may be applied to the upper electrode structure 150, and both the source power and the bias power may be applied to the lower electrode structure 120.

A second sensor SA2 may be positioned between the upper electrode structure 150 and the third power source 165. For example, the second sensor SA2 may be a sensor configured to output a signal for detecting arcing using electric field coupling of RF power applied from the third power source 165. The second sensor SA2 may be configured to electrically transmit and receive signals to and from the arcing detector 141. In this case, the arcing detector 141 may receive an arcing signal from the second sensor SA2. The arcing detector 141 may store arcing information included in the arcing signal. Additionally, the arcing detector 141 may detect whether arcing has occurred within the plasma chamber 110 based on the arcing information included in the arcing signal received from the second sensor SA2.

Conventional arcing detection sensors were configured such that conductive wires pass through a single through hole. Consequently, the through hole had a relatively wide diameter, resulting in a relatively long distance between the conductive wires and the conductive patterns measuring the current and the voltage flowing through the conductive wires. As a result, the determined arcing signal was relatively weak due to the weak coupling between the power flowing through the wires and the conductive patterns. Furthermore, since all the conductive wires pass through a single through hole, it is difficult to specify which conductive wire an abnormal arcing signal was detected in, even when an abnormal arcing signal is detected. Additionally, since a plurality of conductive wires pass through one relatively large through hole, the deviation of the detected arcing signal, depending on the position of the plurality of conductive wires, is relatively large.

In some embodiments, the plasma treating apparatus 100 includes the arcing detection sensor 130 having the plurality of through holes H1, H2, H3, and H4. The conductive wires IH1, IH2, OH1, and OH2 pass through the plurality of through holes H1, H2, H3, and H4, respectively. As a result, the determined arcing signal generated from the conductive wires IH1, IH2, OH1, OH2 may be strong since the distance between the conductive wires IH1, IH2, OH1, and OH2 and the conductive patterns 133a, 133b, 133c, and 133d is relatively short. When an abnormal arcing signal is detected, the specific conductive wire in which the abnormal arcing signal was detected may be easily identified. Moreover, since each of the plurality of conductive wires passes through a relatively small through hole, the position of the plurality of conductive wires may be relatively fixed, thereby improving the deviation of the detected arcing signal. Consequently, arcing occurring within the plasma treating apparatus 100 may be easily detected, and the quality of semiconductor products manufactured using the plasma treating apparatus 100 may be increased.

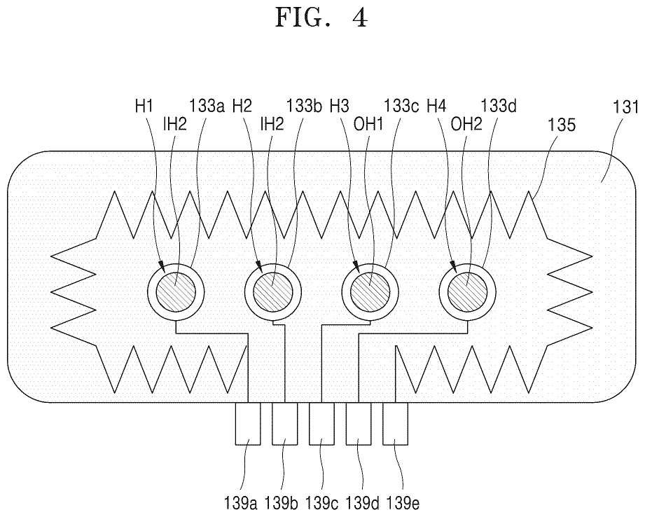

FIG. 4 is a cross-sectional view of an arcing detection sensor 130a along a line corresponding to the first vertical level LV1 in FIG. 2. Since the configuration of the arcing detection sensor 130a illustrated in FIG. 4 is similar to the configuration of the arcing detection sensor 130 illustrated in FIGS. 1 to 3, the description below focuses on the differences between these configurations.

Referring to FIG. 4, the arcing detection sensor 130a may have a configuration similar to the arcing detection sensor 130 illustrated in FIGS. 1 to 3. However, in the arcing detection sensor 130a, a first circular conductive pattern 133a and a second circular conductive pattern 133b are connected to different connection terminals, and a third circular conductive pattern 133c and a fourth circular conductive pattern 133d are connected to different connection terminals. This configuration allows for the separate detection of voltages from each conductive wire passing through the respective through holes.

The arcing detection sensor 130a may include a first circular conductive pattern 133a connected to a first connection terminal 139a, a second circular conductive pattern 133b connected to a second connection terminal 139b, a third circular conductive pattern 133c connected to a third connection terminal 139c, a fourth circular conductive pattern 133d connected to a fourth connection terminal 139d, and a coil conductive pattern 135 connected to a fifth connection terminal 139c. The separate connection of the first circular conductive pattern 133a, the second circular conductive pattern 133b, the third circular conductive pattern 133c, and the fourth circular conductive pattern 133d to the first connection terminal 139a, the second connection terminal 139b, the third connection terminal 139c, and the fourth connection terminal 139d, respectively, enables the arcing detector 141 to detect the voltage of the first inner conductive wire IH1 using the first circular conductive pattern 133a, the voltage of the second inner conductive wire IH2 using the second circular conductive pattern 133b, the voltage of the first outer conductive wire OH1 using the third circular conductive pattern 133c, and the voltage of the second outer conductive wire OH2 using the fourth circular conductive pattern 133d as separate arcing signals. This separate detection capability enhances the ability to identify the specific conductive wire experiencing an arcing event.

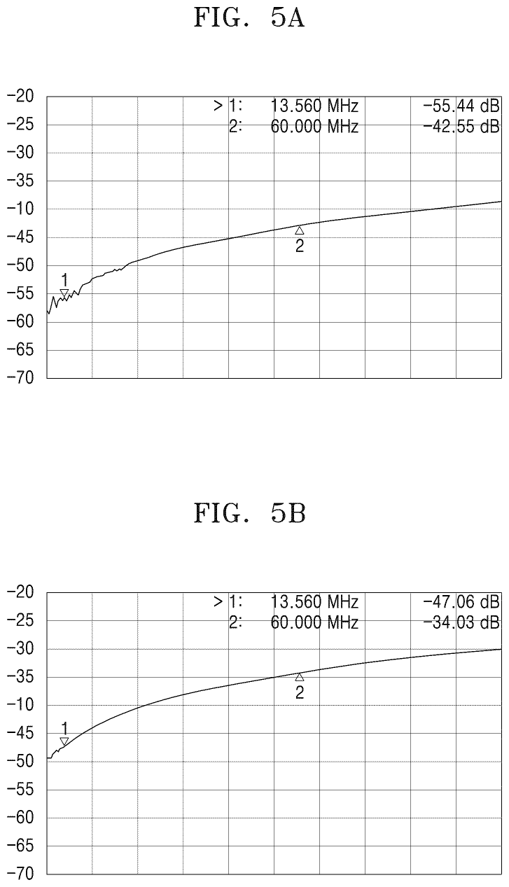

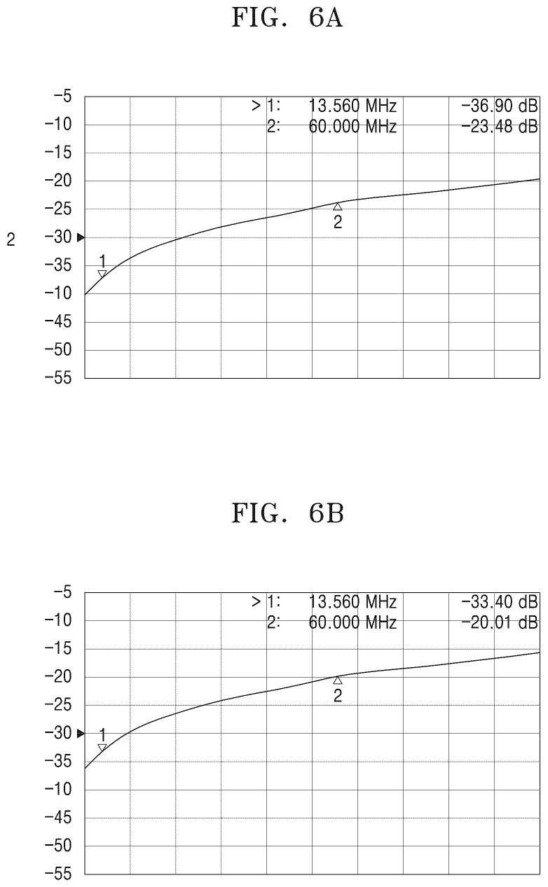

FIGS. 5A and 5B illustrate the degree of arcing signal detection by a conventional arcing detection sensor, while FIGS. 6A and 6B present graphs illustrating the degree of arcing signal detection by an arcing detection sensor according to some embodiments of the present disclosure. FIGS. 5A and 6A depict the degree of arcing signal detection when each conductive wire passes through the center area of a through hole, whereas FIGS. 5B and 6B depict the degree of arcing signal detection when each conductive wire passes through the edge area of the through hole. These graphs provide a comparative analysis of the arcing signal detection capabilities of the conventional arcing detection sensor and the arcing detection sensor according to the embodiments of the present disclosure, considering different positioning scenarios of the conductive wires within the through holes.

Referring to FIG. 5A, regarding the conventional arcing detection sensor, when the conductive wires pass through the center area of the through hole and when power with a frequency of 13.56 MHz is applied to the conductive wires passing through the through hole, the arcing signal generated by the power is attenuated by about 55.44 dB. When power with a frequency of 60 MHz is applied to the conductive wires passing through the through hole, the arcing signal generated by the power is attenuated by about 42.55 dB. Referring to FIG. 5B, in the case of the conventional arcing detection sensor, when the conductive wires pass through the edge area of the through hole and when power with a frequency of 13.56 MHz is applied to the conductive wires passing through the through hole, the arcing signal generated by the power is attenuated by about 47.06 dB. When power with a frequency of 60 MHz is applied to the conductive wires passing through the through hole, the arcing signal generated by the power is attenuated by about 34.03 dB.

Referring to FIG. 6A, in the case of the arcing detection sensor according to some embodiments, when each of the conductive wires passes through the center area of the through hole and when power with a frequency of 13.56 MHz is applied to each of the conductive wires passing through the through hole, the arcing signal generated by the power is attenuated by about 36.9 dB. When power with a frequency of 60 MHz is applied to each of the conductive wires passing through the through hole, the arcing signal generated by the power is attenuated by about 23.48 dB. Referring to FIG. 6B, in the case of the arcing detection sensor according to some embodiments, when each of the conductive wires passes through the edge area of the through hole and when power with a frequency of 13.56 MHz is applied to each of the conductive wires passing through the through hole, the arcing signal generated by the power is attenuated by about 33.4 dB. When power with a frequency of 60 MHz is applied to each of the conductive wires passing through the through hole, the arcing signal generated by the power is attenuated by about 20.01 dB.

Referring to FIGS. 5A, 5B, 6A, and 6B, the arcing detection sensor according to some embodiments can detect a relatively less attenuated arcing signal compared to the conventional arcing detection sensor. Furthermore, the deviation of the detected arcing signal, depending on the position of the conductive wires, is also relatively small.

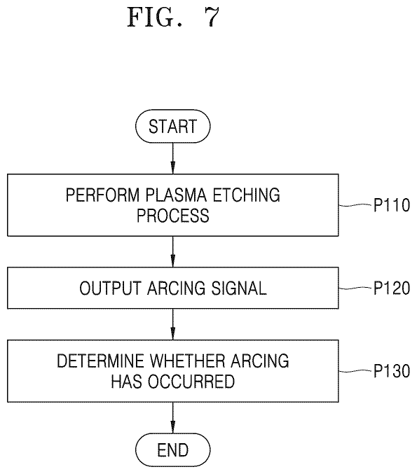

FIG. 7 is a flowchart of a method for detecting arcing using an arcing detection sensor, according to some embodiments. For the purpose of explanation, the plasma treatment performed within plasma treating apparatus 100 is depicted as a plasma etching process in FIG. 7. However, the plasma treatment is not restricted to a plasma etching process and may include other processes, such as a plasma deposition process.

Referring to FIGS. 1 and 7, a plasma etching process is first performed within the plasma treating apparatus 100, according to some embodiments (P110). The plasma etching process involves providing process gas to the upper electrode structure 150, forming plasma gas from the process gas by applying power to the upper electrode structure 150 from the third power source 165, and directing plasma ions from the plasma gas toward the wafer WF supported by the lower electrode structure 120 by applying power to the lower electrode structure 120 from the first power source 161.

During the plasma etching process, at least one sensor included in the plasma treating apparatus 100 outputs an arcing signal to determine whether arcing has occurred in the plasma chamber 110 (P120). The arcing signal may comprise, for example, an arcing signal output from the first sensor SA1, an arcing signal output from the second sensor SA2, and an arcing signal output from the arcing detection sensor 130. These arcing signals are then transmitted to the arcing detector 141.

The arcing detector 141 determines whether arcing has occurred in the plasma chamber 110 based on the arcing signals received from the first sensor SA1, the second sensor SA2, and the arcing detection sensor 130 (P130). The occurrence of arcing may be determined, for example, by analyzing the magnitude or shape of each arcing signal. If the magnitude or shape of the arcing signal output from the arcing detection sensor 130 changes significantly, the arcing detector 141 may conclude that arcing has occurred in the plasma chamber 110.

Upon determining the occurrence of arcing within the plasma chamber 110, the control device 143 adjusts the process environment within the plasma chamber 110 to mitigate the effects of the arcing.

Although the present disclosure has been described with reference to specific embodiments, it should be understood that various modifications and changes may be made without departing from the spirit and scope of the following claims.

What is claimed is:

1. An arcing detection sensor comprising:
a substrate portion having a plurality of through holes;
a plurality of circular conductive patterns, each circular conductive pattern arranged along a circumference of a respective through hole of the plurality of through holes; and
a coil conductive pattern surrounding the plurality of circular conductive patterns;
wherein each circular conductive pattern is configured to detect a voltage of a respective conductive wire passing through the respective through hole, and the coil conductive pattern is configured to detect currents of the conductive wires passing through the plurality of through holes.

2. The arcing detection sensor of claim 1, wherein the plurality of through holes comprise a first through hole, a second through hole, a third through hole, and a fourth through hole horizontally spaced apart in a center area of the substrate portion, and the plurality of circular conductive patterns comprise a first circular conductive pattern surrounding the first through hole, a second circular conductive pattern surrounding the second through hole, a third circular conductive pattern surrounding the third through hole, and a fourth circular conductive pattern surrounding the fourth through hole.

3. The arcing detection sensor of claim 2, wherein the first circular conductive pattern and the second circular conductive pattern are connected to a first connection terminal disposed on a side of the substrate portion, and the third circular conductive pattern and the fourth circular conductive pattern are connected to a second connection terminal disposed on the side of the substrate portion.

4. The arcing detection sensor of claim 2, wherein the coil conductive pattern is connected to a third connection terminal disposed on a side of the substrate portion.

5. The arcing detection sensor of claim 2, wherein the first circular conductive pattern is connected to a first connection terminal disposed on a side of the substrate portion, the second circular conductive pattern is connected to a second connection terminal disposed on the side of the substrate portion, the third circular conductive pattern is connected to a third connection terminal disposed on the side of the substrate portion, and the fourth circular conductive pattern is connected to a fourth connection terminal disposed on the side of the substrate portion.

6. The arcing detection sensor of claim 5, wherein the coil conductive pattern is connected to a fifth connection terminal disposed on the side of the substrate portion.

7. The arcing detection sensor of claim 1, wherein a diameter of each of the plurality of through holes is about 1.1 times to about 1.5 times a diameter of the respective conductive wire passing through the respective through hole.

8. A arching detection sensor constitutes a plasma treating apparatus that comprises a heater that is configured to heat the wafer and plasma chamber that is configured to provide a treatment space comprising:
a substrate portion having a plurality of through holes;
a plurality of circular conductive patterns, each circular conductive pattern arranged along a circumference of a respective through hole of the plurality of through holes; and
a coil conductive pattern surrounding the plurality of circular conductive patterns;
wherein each circular conductive pattern is configured to detect a voltage of a respective conductive wire passing through the respective through hole, and the coil conductive pattern is configured to detect currents of the conductive wires passing through the plurality of through holes.

9. The plasma treating apparatus of claim 8, wherein the plurality of through holes comprise a first through hole, a second through hole, a third through hole, and a fourth through hole horizontally spaced apart in a center area of the substrate portion, and the plurality of circular conductive patterns comprise a first circular conductive pattern surrounding the first through hole, a second circular conductive pattern surrounding the second through hole, a third circular conductive pattern surrounding the third through hole, and a fourth circular conductive pattern surrounding the fourth through hole.

10. The plasma treating apparatus of claim 9, wherein the heater comprises an inner conductive wire and an outer conductive wire, each wound inside the heater, the inner conductive wire is configured to pass through the first through hole and the second through hole, and the outer conductive wire is configured to pass through the third through hole and the fourth through hole.

11. The plasma treating apparatus of claim 10, wherein the voltage flowing through the inner conductive wire is determined based on electric field coupling between the inner conductive wire and the first circular conductive pattern and the second circular conductive pattern, and the voltage flowing through the outer conductive wire is determined based on electric field coupling between the outer conductive wire and the third circular conductive pattern and the fourth circular conductive pattern.

12. The plasma treating apparatus of claim 10, wherein the current flowing through the inner conductive wire and the outer conductive wire is determined based on magnetic field coupling between the inner conductive wire, the outer conductive wire, and the coil conductive pattern.

13. The plasma treating apparatus of claim 9, wherein the first circular conductive pattern and the second circular conductive pattern are connected to a first connection terminal disposed on a side of the substrate portion, the third circular conductive pattern and the fourth circular conductive pattern are connected to a second connection terminal disposed on the side of the substrate portion, and the coil conductive pattern is connected to a third connection terminal disposed on the side of the substrate portion.

14. The plasma treating apparatus of claim 9, wherein the first circular conductive pattern is connected to a first connection terminal disposed on a side of the substrate portion, the second circular conductive pattern is connected to a second connection terminal disposed on the side of the substrate portion, the third circular conductive pattern is connected to a third connection terminal disposed on the side of the substrate portion, the fourth circular conductive pattern is connected to a fourth connection terminal disposed on the side of the substrate portion, and the coil conductive pattern is connected to a fifth connection terminal disposed on the side of the substrate portion.

15. The plasma treating apparatus of claim 9, wherein a diameter of each of the plurality of through holes is about 1.1 times to about 1.5 times a diameter of the respective conductive wire passing through the respective through hole.

16. The plasma treating apparatus of claim 9, further comprising an arcing detector connected to the arcing detection sensor and configured to detect whether arcing has occurred based on an arcing signal received from the arcing detection sensor.

17. The plasma treating apparatus of claim 16, further comprising a control device configured to control a process environment of the plasma chamber when arcing is detected by the arcing detector.

18. An arcing detection sensor comprising:
a substrate portion having a first through hole, a second through hole, a third through hole, and a fourth through hole horizontally spaced apart;
a plurality of circular conductive patterns, wherein the plurality of circular conductive patterns comprise a first circular conductive pattern arranged along a circumference of the first through hole, a second circular conductive pattern arranged along a circumference of the second through hole, a third circular conductive pattern arranged along a circumference of the third through hole, and a fourth circular conductive pattern arranged along a circumference of the fourth through hole; and
a coil conductive pattern surrounding the plurality of circular conductive patterns, wherein each circular conductive pattern is configured to detect a voltage of a respective conductive wire passing through the respective through hole by electric field coupling, and the coil conductive pattern is configured to detect currents of the conductive wires passing through the plurality of through holes.

19. The arcing detection sensor of claim 18, wherein the first circular conductive pattern and the second circular conductive pattern are connected to a first connection terminal disposed on a side of the substrate portion, the third circular conductive pattern and the fourth circular conductive pattern are connected to a second connection terminal disposed on the side of the substrate portion, and the coil conductive pattern is connected to a third connection terminal disposed on the side of the substrate portion.

20. The arcing detection sensor of claim 18, wherein a diameter of each of the plurality of through holes is about 1.1 times to about 1.5 times a diameter of the respective conductive wire passing through the respective through hole.
